(19) United States
(12) Patent Application Publication
(10) Pub. No.: US 2006/0194453 A1
(43) Pub. Date: Aug. 31, 2006

(54) Silicon dioxide film and process for preparation of the same

(76) Inventors: Yasushi Murakami, Nagano (JP); Masayuki Harano, Nagano (JP); Yoshio Takasu, Nagano (JP); Yoshio Taniguchi, Nagano (JP)

Correspondence Address: NIXON PEABODY, LLP, 401 9TH STREET, NW, SUITE 900, WASHINGTON, DC, 20004-2128, US

(21) Appl. No.: 10/550,859

(22) PCT Filed: Mar. 25, 2004
(86) PCT No.: PCT/JP04/04142

§ 371 Date: Sep. 26, 2005

(30) Foreign Application Priority Data
Mar. 25, 2003 (JP) 2003-083915

(51) Int. Cl. H01L 23/58; H01L 21/31

(52) U.S. Cl. 438/787; 257/632

(57) ABSTRACT

A transparent amorphous silicon dioxide film containing many fine voids, characterized in that the refractive index (for light at λ=500 nm) is in the range of 1.01 to 1.40 and that 80 vol. % or more of the fine voids have a diameter of 5 nm or less, has a low refractive index and excellent physical strength such as high scratch resistance, so that it is advantageously employable as an optical film of an optical device for various uses.

### FIELD OF THE INVENTION

This invention relates to a transparent amorphous silicon dioxide film having a low refractive index. The film can be advantageously used as an optical film to be provided on an optical device.

### BACKGROUND OF THE INVENTION

Metal oxide films such as a silicon dioxide film having a low refractive index, and a titanium dioxide film having a high refractive index, are used as, for example, multi-layered reflection films, antireflection films and photonic crystals of various optical devices.

The transparent metal oxide film has been conventionally prepared by a gas phase-accumulation method such as a vapor-deposition process or a sputtering process. However, the process for preparing the metal oxide film according to the gas phase-accumulation method is industrially disadvantageous because a complicated production apparatus is needed, because the process must be precisely operated and further because it takes relatively long time to complete the process.

Accordingly, as a method replacing the gas phase-accumulation method, a sol-gel process has been developed. The sol-gel process is a metal oxide-preparation process comprising the steps of: hydrolyzing a metal alkoxide dissolved in a solvent, and then condensation-polymerizing the hydrolyzed product. Since a metal oxide film of high quality can be obtained by means of a simple production apparatus with short-time procedures, the sol-gel process is often employed at present to produce, particularly, an optical film formed on a surface of an optical device.

“Application of Sol-Gel Method (written in Japanese)”, by SAKUHANA Sumio, Agune-Shofu sha (1997), pp. 203 describes that a titanium dioxide (TiO₂) film and a silicon dioxide (SiO₂) film are alternately deposited by the sol-gel process to prepare an antireflection film which can remarkably decrease the reflection.

“Antireflection Film of Superfine Particles (written in Japanese)”, by WAKABAYASHI Atsumi, O plus E, vol. 24, No. 11, pp. 1231-1235 (November 2002) describes a process to produce an antireflection film from nanometer-sized fine particles (what is called, superfine particles) of antimony-containing tin oxide or tin-containing indium oxide.

Further, “Emission-Extraction Efficiency Improved by Aerogel (written in Japanese)”, by YOKOKAWA Hiroshi, which was a textbook of the 9th seminar “Challenge to the Next Generation Organic EL: driving system for high efficiency, long life and full-color displaying” (2001) organized by the subcommittee of Molecular Electronics and Bioelectronics in The Japan Society of Applied Physics describes that a silica aerogel film shows improved efficiency in taking out light from an organic electroluminescence (EL) device. According to the textbook, the refractive index of the silica aerogel film can be controlled in the range of 1.10 to 1.01 by changing the density of silica aerogel.

Jpn. J. Appl. Phys., Vol. 41(2002), pp. L291-L293 describes a photonic crystal-preparation process. In the process, a mold is immersed in titanium dioxide gel prepared from concentrated alkoxide, and then dried and fired to prepare a photonic crystal.

Thus, a metal oxide film usable as an optical film of high quality can be obtained by means of a relatively simple apparatus with relatively simple procedures if the sol-gel process, which has been developed as an industrially advantageous process to take the place of the gas phase-accumulation method, is adopted. However, the known sol-gel process still dose not give a silicon dioxide film employable as an optical film having satisfactorily low refractive index.

In addition, although the sol-gel process is reported to make it possible to produce a silicon dioxide film as an optical film having a desired low refractive index, the film-production process according to the known sol-gel process has not been sufficiently studied yet from the viewpoint of industrially employable process.

As described above, the known optical film-production process according to the sol-gel process or to the aerogel method is still not on a satisfying level. Further, the optical film produced by the known process does not have enough physical strength and surface hardness. An antireflection film formed on an optical device, such as an electroluminescence (EL) device (particularly, an organic electroluminescence device), an optical lens or an display (e.g., CRT), often comes into contact with operators' hands or other devices, and hence ought to have high scratch resistance. However, the optical film formed by the sol-gel process or by the aerogel method, in which the refractive index is controlled by incorporating many bubbles, is not liable to have high scratch resistance because of the bubbles. Further, for the same reason, that optical film is also poor in mechanical strength such as bending resistance and in heat resistance.

### DISCLOSURE OF THE INVENTION

It is an object of the present invention to provide a transparent silicon dioxide film having a low refractive index, high scratch resistance, satisfying physical strength and excellent heat resistance.

The present invention resides in a transparent amorphous silicon dioxide film containing a large number of fine voids and showing a refractive index (for light at λ=500 nm) in the range of 1.01 to 1.40, wherein 80 vol. % or more of the fine voids have diameters of 5 nm or less.

Preferred embodiments of the invention are as follows.

(1) The film has a void volume ratio of 50% or more.

(2) 80 vol. % or more of the fine voids have diameters of 2 nm or less.

(3) 90 vol. % or more of the fine voids have diameters of 2 nm or less.

(4) The film is obtained by firing a film formed according to a sol-gel process.

(5) The film is prepared by a process comprising the steps of:

subjecting a silicon alkoxide to hydrolysis and condensation-polymerization in an alcoholic solvent in the presence of water and at least one compound selected from the group consisting of hydroxyaldehyde compounds, hydroxycarboxylic acid compounds, allyl alcohol compounds and hydroxynitrile compounds, to prepare sol;

forming the sol to produce a film, and

firing the film.

(6) The step for subjecting the silicon alkoxide in to hydrolysis and condensation polymerization according to the process of (5) above is performed further in the presence of at least one salt catalyst selected from the group consisting of salts between weak acids and weak bases, salts of hydrazine compounds, salts of hydroxylamine compounds and salts of amidine compounds.

(7) The film has a thickness of 10 nm to 20 μm.

The ratio (vol. %) of all the fine voids or of the fine voids having particular diameters in the silicon dioxide film of the invention is determined in the following manner.

A void volumes per mass of voids of specific diameters are measured by means of a nitrogen-adsorption apparatus. Then, the density is measured by means of a densitometer, and the void volumes per mass are multiplied by the measured density to obtain void volumes per volume of voids of specific diameters. The obtained void volumes per volume are converted in percentage terms to give the ratio of the fine voids of the particular diameters.

### DETAILED DESCRIPTION OF THE INVENTION

The amorphous silicon dioxide film of the invention and the process for preparation are explained below.

(Amorphous Silicon Dioxide Film)

As compared with a silicon dioxide film obtained by the known sol-gel process, the silicon dioxide film of the invention is mainly characterized in that a large number of voids (bubbles) contained therein have sizes in the order of certain nanometers and hence are remarkably small. Since the silicon dioxide film of the invention has a lot of very small voids, the film has not only high transparency but also a desired low refractive index, high mechanical strength (particularly, high scratch resistance and high bending resistance) and excellent heat resistance (against thermal deformation).

The silicon dioxide film of the invention can be produced by a process comprising the steps of: hydrolyzing and condensation-polymerizing a silicon alkoxide in an alcoholic solvent in the presence of water and at least one compound selected from the group consisting of hydroxyaldehyde compounds, hydroxycarboxylic acid compounds, allyl alcohol compounds and hydroxynitrile compounds, to prepare sol (low viscous liquid mixture); forming a film from the sol; and heating to fire the sol film. This process is easily carried out from the industrial viewpoint.

In the process, the step for hydrolysis and condensation polymerization of silicon alkoxide is preferably carried out further in the presence of at least one salt catalyst selected from the group consisting of salts between weak acids and weak bases, salts of hydrazine compounds, salts of hydroxylamine compounds and salts of amidine compounds.

As a silicon dioxide film-production process according to the sol-gel process, the known and practically used process comprises the steps of: hydrolyzing and condensation-polymerizing a silicon alkoxide in an alcoholic solvent to prepare sol, forming a film from the sol, and heating to fire the sol film.

In the conventional silicon dioxide film-production process according to the sol-gel process, a tetraalkoxysilicon (such as tetramethoxysilicon, tetraethoxysilicon, tetra-n-propoxysilicon, tetraisopropoxysilicon, tetra-n-butoxysilicon, tetraisobutoxysilicon or tetra-t-butoxysilicon) or a derivative thereof is dissolved in a lower aliphatic alcohol solvent such as methanol, ethanol, n-propanol, isopropanol, n-butanol or isobutanol. After water is added to the solution, the solution is stirred and mixed at room temperature or, if desired, at an elevated temperature, so that the tetraalkoxysilicon or derivative thereof is at least partly hydrolyzed and then the hydrolyzed product undergoes the condensation polymerization reaction to produce a condensation polymer. While the polymerization reaction is still insufficiently developed, the polymer in the state of low viscous sol is shaped into a film.

In the process for preparation of the amorphous silicon dioxide film of the invention, the step for subjecting the silicon alkoxide to hydrolysis and condensation polymerization is carried out in the presence of at least one compound (hydrolysis accelerator) selected from the group consisting of hydroxyaldehyde compounds (or hydroxy-ketone compounds), hydroxycarboxylic acid compounds, allyl alcohol compounds and hydroxynitrile compounds. Examples of the hydroxyaldehyde compounds (or hydroxy-ketone compounds) include hydroxyacetone, acetoin, 3-hydroxy-3-methyl-2-butanone, and fructose. Examples of the hydroxycarboxylic acid compounds include glycolic acid, lactic acid, hydroxyisobutyric acid, thioglycolic acid, glycolic esters, lactic esters, 2-hydroxy-isolactic esters, thioglycolic esters, malic acid, tartaric acid, citric acid, malic esters, tartaric esters, and citric esters. Examples of the allyl alcohol compounds include 1-buten-3-ol, 2-methyl-3-buten-2-ol, 1-penten-3-ol, 1-hexen-3-ol, crotyl alcohol, 3-methyl-2-buten-1-ol, and cinnamyl alcohol. Examples of the hydroxynitrile compounds include acetonecyanohydrin.

As described above, the step for subjecting the silicon alkoxide to hydrolysis and condensation polymerization is preferably carried out further in the presence of at least one compound (salt catalyst) selected from the group consisting of salts between weak acids and weak bases, salts of hydrazine compounds, salts of hydroxylamine compounds and salts of amidine compounds. Examples of the salts between weak acids and weak bases include ammonium carboxylate (e.g., ammonium acetate, ammonium formate), ammonium carbonate, and ammonium hydrogen carbonate. Examples and functions of the salt catalyst selected from the group consisting of salts of hydrazine compounds, salts of hydroxylamine compounds and salts of amidine compounds are described in JP-A-2000-26849, in which they are mentioned as the salt catalyst used in preparation of photochromic titanium oxide gel and glass ware thereof.

In the preparation of the amorphous silicon dioxide film of the invention, the hydrolysis accelerator is used in the step for subjecting the silicon alkoxide to hydrolysis and condensation polymerization. The hydrolysis is, therefore, so accelerated that plural alkoxy groups of each silicon alkoxide molecule are almost simultaneously hydrolyzed and converted into active hydroxyl groups. Accordingly, it is considered that polymer chains are likely to extend not linearly but three-dimensionally. As a result, a polymer of matrix structure is predominantly formed rather than a polymer of long chain structure. Since the resulting condensation polymer has a matrix structure, voids formed in the polymer are presumed to have very small sizes comparable to the size of the molecules.

The sol prepared by the hydrolysis and condensation polymerization of silicon alkoxide is then shaped into a film. For forming the film, known coating methods can be employed. The sol may be, for example, evenly spread by spin-coating on a substrate, or otherwise a substrate may be dipped in and drawn up from the sol (dip-coating). The substrate is preferably beforehand subjected to a surface treatment such as plasma treatment under oxygen gas atmosphere.

The formed sol film is then heated and fired to prepare the desired amorphous silicon dioxide film of the invention. The firing is generally carried out at a temperature of 100 to 1,100° C. Not only the void ratio but also the refractive index of the formed amorphous silicon dioxide film can be controlled by changing conditions in preparing the sol (such as temperature and time in mixing and stirring the sol) or by selecting the firing temperature.

### EXAMPLE

### Example 1

### Preparation of an Amorphous Silicon Dioxide Film Having a Low Refractive Index

In a stream of nitrogen gas, tetramethoxysilicon (12.5 mmol) and hydroxyacetone (hydrolysis accelerator, 12.5 mmol) were added to a solvent (16.15 mL, methanol containing 62.5 mmol of ion-exchanged water) and mixed. Independently, ammonium acetate (1.25 mmol) was added to another solvent (5 mL, methanol) and mixed. The two solutions were mixed at 25° C. for 24 hours, to prepare a sol mixture.

The sol mixture was spread with a spin-coater on a silicon substrate, to form a coated film having an even thickness. The coated film was then fired at 300° C. for 2 hours, to prepare an amorphous silicon dioxide film having the thickness of 130 nm. The refractive index (at 500 nm) of the film was found 1.16. It was also found that the film contained many fine voids, that the void ratio was 80% and that 90 vol. % or more of the fine voids had diameters of 2 nm or less. The obtained silicon dioxide film had a surface of high scratch resistance.

### INDUSTRIAL UTILITY

The amorphous silicon dioxide film of the invention has a low refractive index, high physical strength (e.g., scratch resistance) and excellent heat resistance, and is therefore advantageously employable as an optical film of optical device for various uses.

What is claimed is:

1. A transparent amorphous silicon dioxide film containing a large number of fine voids and showing a refractive index for light at λ=500 nm in the range of 1.01 to 1.40, wherein 80 vol. % or more of the fine voids have diameters of 5 nm or less.

2. The amorphous silicon dioxide film of claim 1, which has a void volume ratio of 50% or more.

3. The amorphous silicon dioxide film of claim 1, wherein 80 vol. % or more of the fine voids have diameters of 2 nm or less.

4. The amorphous silicon dioxide film of claim 1, wherein 90 vol. % or more of the fine voids have diameters of 2 nm or less.

5. The amorphous silicon dioxide film of claim 1, which is a product obtained by firing a film formed according to a sol-gel process.

6. A process for preparation of the amorphous silicon dioxide film of claim 1, comprising the steps of:
subjecting a silicon alkoxide to hydrolysis and condensation-polymerization in an alcoholic solvent in the presence of water and at least one compound selected from the group consisting of hydroxyaldehyde compounds, hydroxycarboxylic acid compounds, allyl alcohol compounds and hydroxynitrile compounds, to prepare sol;
forming the sol to produce a film, and
firing the film.

7. The process of claim 6, wherein the step for subjecting the silicon alkoxide to hydrolysis and condensation polymerization is performed further in the presence of at least one salt catalyst selected from the group consisting of salts between weak acids and weak bases, salts of hydrazine compounds, salts of hydroxylamine compounds and salts of amidine compounds.
